(19) United States
(12) Patent Application Publication
(10) Pub. No.: US 2009/0102881 A1
(43) Pub. Date: Apr. 23, 2009

(54) Surface Metallization Of Metal Oxide Pre-Ceramic

(75) Inventors: Henry Roskos, Los Gatos, CA (US); Fred Johnson, Pleasanton, CA (US)

Correspondence Address: FISH & ASSOCIATES, PC;ROBERT D. FISH, 2603 Main Street, Suite 1000, Irvine, CA, 92614-6232, US

(73) Assignee: MVM TECHNOLOGIES, INC., San Clemente, CA (US)

(21) Appl. No.: 12/251,706

(22) Filed: Oct. 15, 2008

Related U.S. Application Data
(60) Provisional application No. 60/980,551, filed on Oct. 17, 2007.

(51) Int. Cl. H05K 1/00; B41J 2/015

(52) U.S. Cl. 347/20; 174/254

(57) ABSTRACT

Fine conductor lines (those having a width of ≦50 μM) are disposed on a flexible metal oxide containing substrate by masking portions of the substrate, and then surface metallizing unmasked portions of the substrate. Polymeric preceramic films are preferred, especially those having a glass temperature of at least 300° C. and those of the PZT family, or those containing BeO. All suitable reducing gasses are contemplated, including especially H2. All suitable masking materials are similarly contemplated, including especially titanium, titanium nitride, tungsten nitride, tantalum, and tantalum nitride. In especially preferred embodiments the conductor lines have a width of ≦25 μM, ≦15 μM, ≦5 μM, and even ≦1 μM. The lines can advantageously compose a circuit that is coupled to a piezoelectric or other mechanical actuator, which in turn can be fluidly coupled to a fluid reservoir.

This application claims priority to provisional application 60/980,551, filed Oct. 17, 2007 incorporated by reference in its entirety.

### FIELD OF THE INVENTION

The field of the invention is electrical circuits.

### BACKGROUND

Both additive and subtractive processes are known for laying down metal traces atop a silicon wafer, and on various hard substrates. Issues arise, however, when laying down metal traces on flexible (including semi-flexible) substrates, including for example plastic films. In such cases the substrate is often destroyed by the high temperatures used during processing, or traces fail to adhere properly to the substrate.

It is exceptionally difficult to lay down metal traces on metal oxides. Sputtering can be used for such purposes, but adhesion is poor. Adhesion can be improved by subjecting the traces to laser beams, but even then the resulting traces are not very thick. For example, it has been reported that strongly adherent copper traces can be built up on a sapphire substrate (Al2O3) with sequential sputter deposition of copper irradiated with XeCl (308 nm) laser at energy densities >0.35 J cm². See Pedrazal, Anthony J. et al., “Enhanced metal-ceramic adhesion by sequential sputter deposition and pulsed laser melting of copper films on sapphire substrates”, Journal of Materials Science, Vol. 24, No. 1, pp 115-123 (January 1989). This article, and all other extraneous materials discussed herein are incorporated by reference in their entirety. Where a definition or use of a term in an incorporated reference is inconsistent or contrary to the definition of that term provided herein, the definition of that term provided herein applies and the definition of that term in the reference does not apply.

Metal oxides can, of course, be reduced to their metal by reduction in a gaseous environment. For example, in production of silica (SiO₂) containing ceramics, the blue-green and green colors of oxide containing glazes result from reduction of iron and copper oxides, respectively, by carbon monoxide. In production of semiconductors, it is also known to lay down a copper oxide tape (the so-called green tape process), or a copper-oxide coated copper powder, and then reduce the oxide to form a substantially pure metal trace. See U.S. Pat. No. 4,600,604 to Siuta (July 1986).

In any event, all of those prior art processes can be difficult to implement, and are poorly suited to production of fine conductor lines, such as that needed for large scale ink jet print heads. See, e.g., U.S. Pat. No. 5,818,481 to Hotomi et al. (October 1998), in which ink jet print heads are produced by depositing a piezoelectric material onto a non-piezoelectric substrate, and then depositing electric traces onto the substrate in a conventional manner.

Thus, what is still needed are structures and methods in which fine conductor lines (those having a width of ≦50 μM) are formed directly on the surface of flexible metal oxide containing substrate.

### SUMMARY OF THE INVENTION

The present invention provides structures and methods in which fine conductor lines (those having a width of ≦50 μM) are disposed on a flexible metal oxide containing substrate by masking portions of the substrate, and then surface metallizing unmasked portions of the substrate.

The substrate is preferably a polymeric preceramic film having a glass temperature of at least 300° C. and more preferably at least 400° C. Especially preferred substrates are of the PZT family, including those described in U.S. Pat. No. 5,656,073 to Glaubitt et al. (August 1997), or those containing BeO. Ceramics are conventionally defined as products made from inorganic, non-metallic materials with a crystalline structure, (e.g., clay), which are hardened by firing at high temperature. A pre-ceramic is a ceramic material that has not yet been hardened by firing at high temperature. As used herein the term “ceramic” is broadened to include metal oxides that can be hardened when raised to their glass temperatures.

All suitable reducing gasses are contemplated, including especially H₂. All suitable masking materials are similarly contemplated, including especially titanium, titanium nitride, tungsten nitride, tantalum, and tantalum nitride.

In especially preferred embodiments the conductor lines have a width of ≦25 μM, ≦15 μM, ≦5 μM, and even ≦1 μM. The lines can advantageously compose a circuit that is coupled to a piezoelectric or other mechanical actuator, which in turn can be fluidly coupled to a fluid reservoir. The circuit can have any realistic number of layers, including especially at least five layers.

Various objects, features, aspects and advantages of the present invention will become more apparent from the following detailed description of preferred embodiments of the invention, along with the accompanying drawings in which like numerals represent like components.

### BRIEF DESCRIPTION OF THE DRAWING

FIG. 1A is a plan view of a portion of a partially formed printhead, in which a patterned mask has been applied on top of a metal oxide containing substrate.

FIG. 1B is a side view of the partially formed printhead of FIG. 1A taken along plane 1B-1B, before application of a reducing gas.

FIG. 1C is a side view of the partially formed printhead of FIG. 1A, taken along plane 1B-1B, after application of a reducing gas.

FIG. 1D is a side view of the partially formed printhead of FIG. 1A, taken along plane 1B-1B, after application of a reducing gas, and electroplating of the metal trace formed in the surface of the substrate.

FIG. 1E is a side view of the partially formed printhead of FIG. 1A, taken along plane 1B-1B, after removal of the mask.

FIG. 2A is a plan view of a portion of the partially formed printhead of FIG. 1A, to which has been added a sacrificial photoresist.

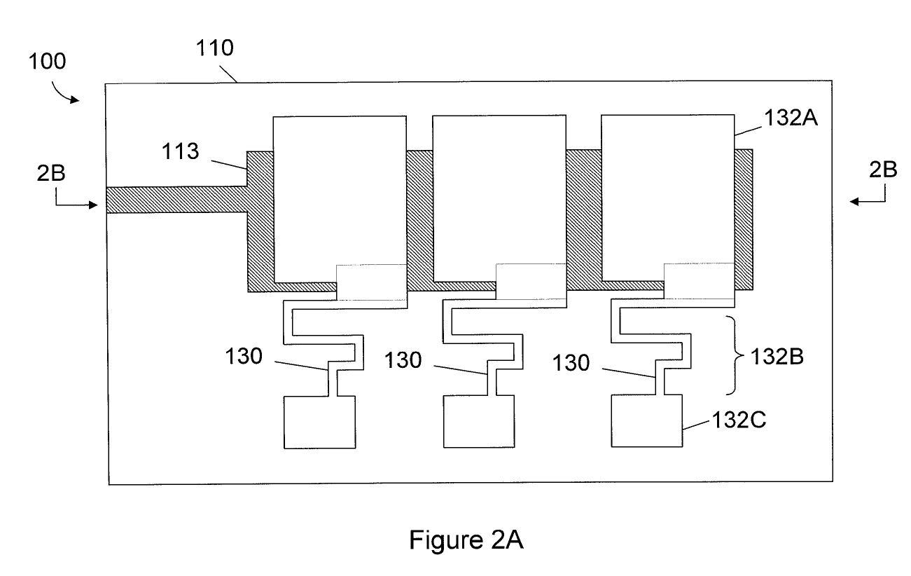

FIG. 2B is a section of the printhead of FIG. 2A taken along plane 2B-2B.

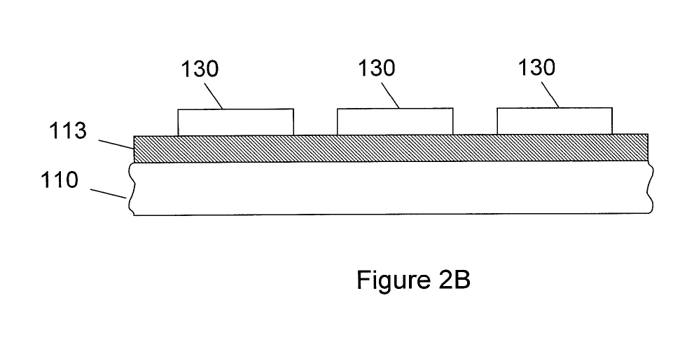

FIG. 3A is a plan view of a portion of the partially formed printhead of FIG. 2A, to which has been added a layer of piezo-electrically active material.

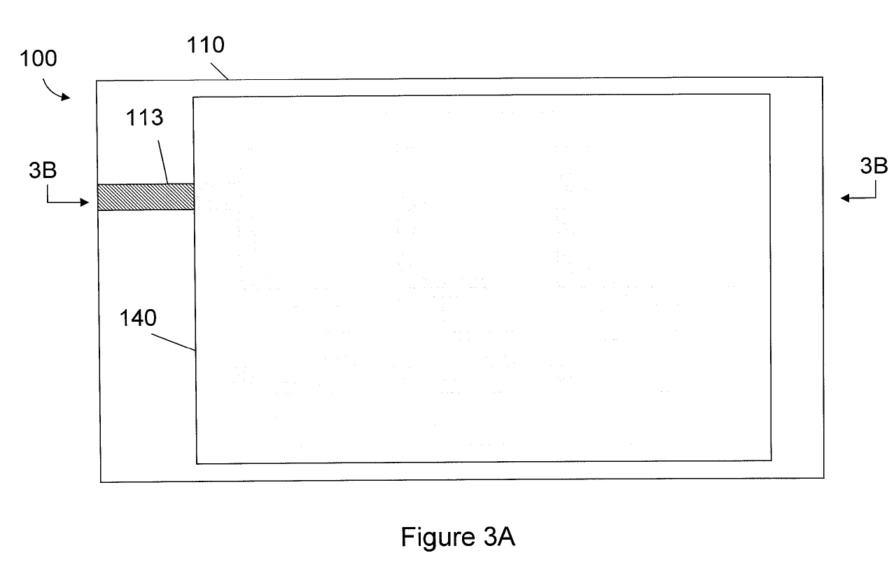

FIG. 3B is a section of the printhead of FIG. 3A taken along plane 3B-3B.

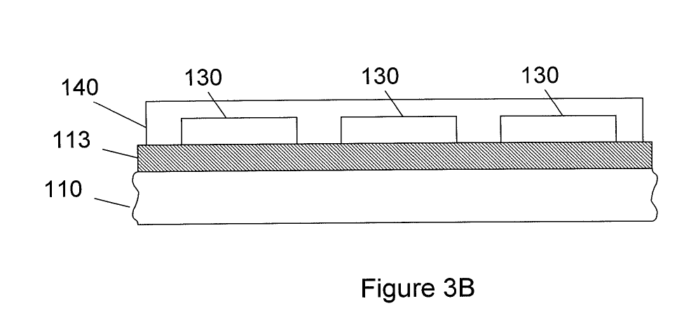

FIG. 4A is a plan view of a portion of the partially formed printhead of FIG.3A, to which has been added an upper conductive trace.

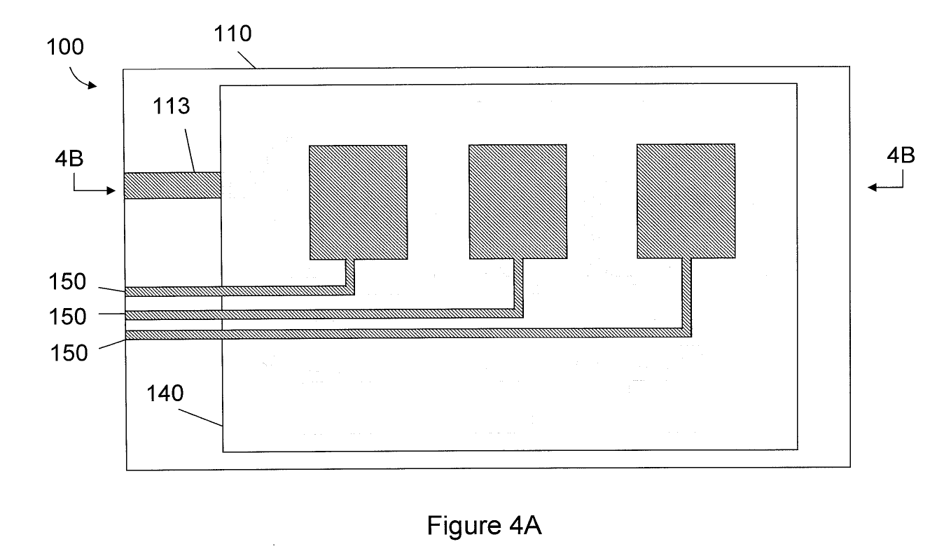

FIG. 4B is a section of the printhead of FIG. 4A taken along plane 4B-4B.

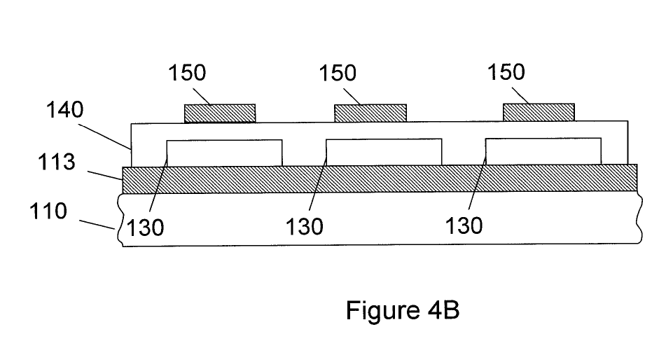

FIG. 5A is a plan view of a portion of the partially formed printhead of FIG. 4A, to which has been added nozzles and through holes to a reservoir.

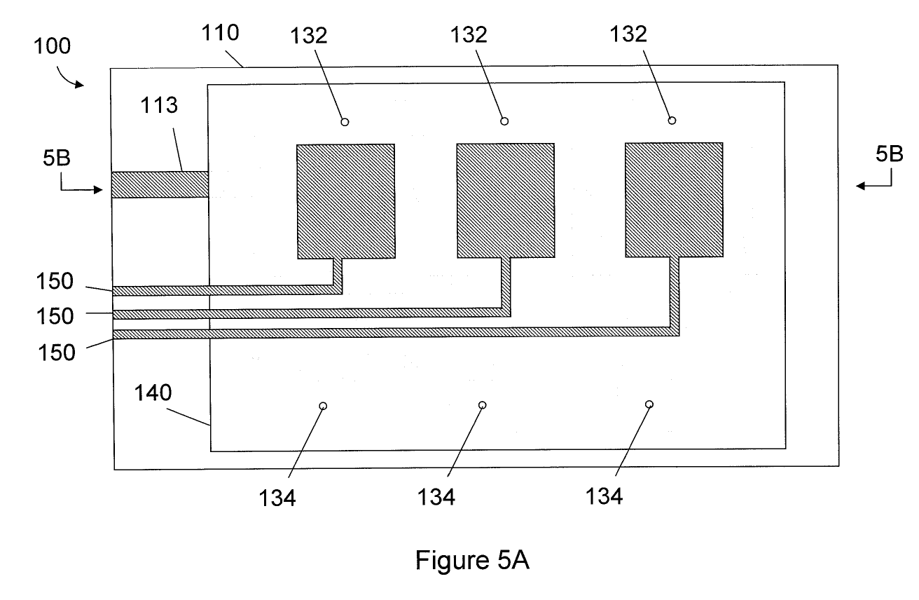

FIG. 5B is a section of the printhead of FIG. 5A taken along plane 5B-5B.

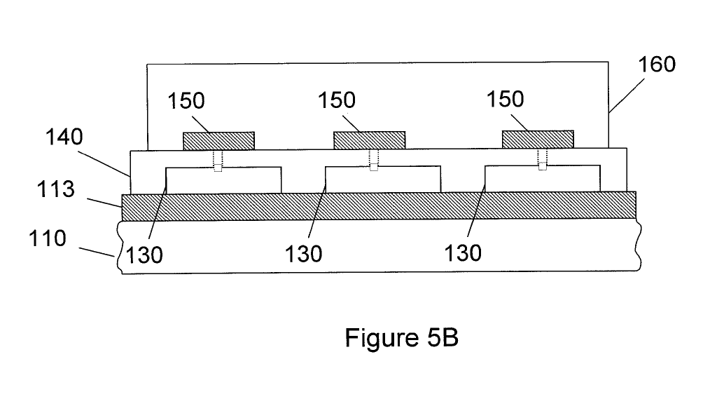

FIG. 6 is a flow chart showing preferred methods of configuring a conductive trace on a flexible substrate.

### DETAILED DESCRIPTION

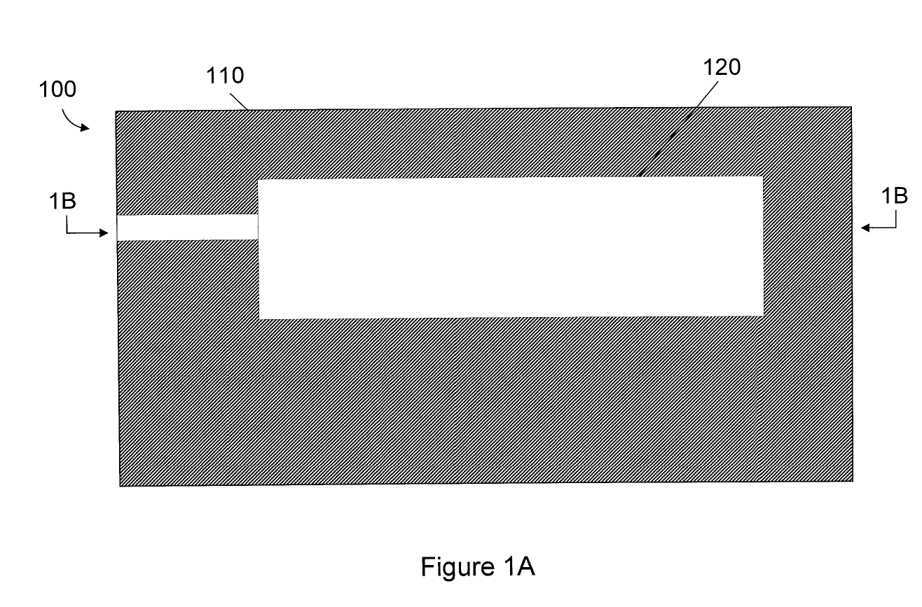

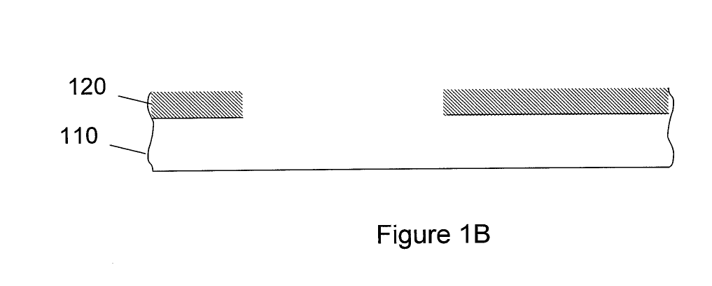

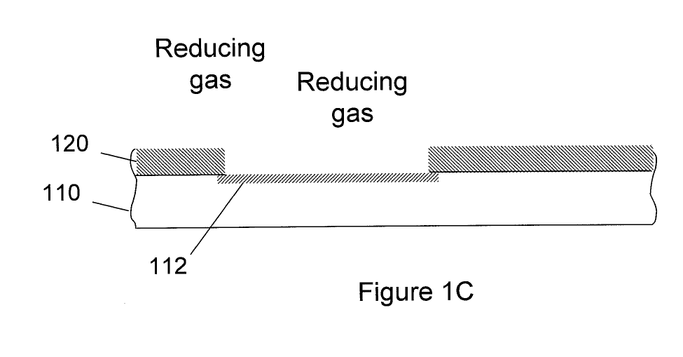

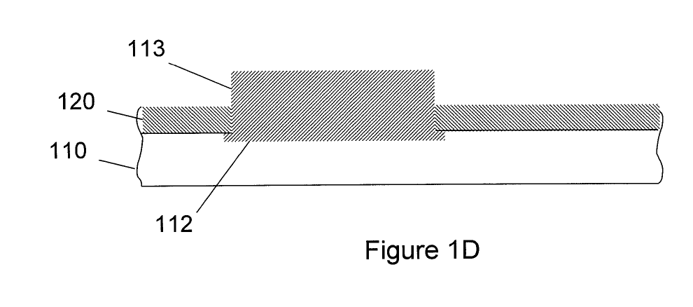

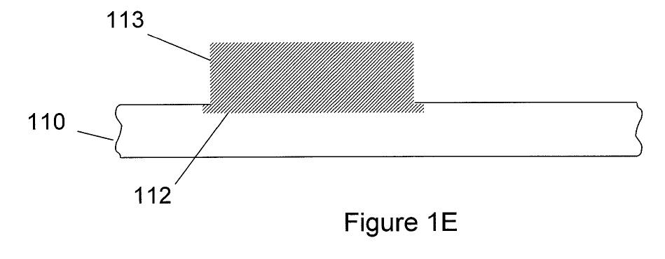

In FIGS. 1A and 1B, a device 100 includes a substrate layer 110 over which has been placed a patterned photoresist mask 120.

The substrate layer 110 is preferably a metal oxide containing film, especially one containing at least one of ZnO, PB(Zr,Ti)O₃, (Pb, La)(Zr, Ti)O₃, LiTaO₃, LiNbO₃, SiO₂, Ta₂O₅, Nb₂O₅, BeO, Li₂B₄0₇, KNbO₃, SnO₂, In2O₃, TiO, LiV₂O₄, ReO₃, LaTiO₃, SrVO₃, CaCrO₃, V₂O₃, VO₂, CrO₂ and IrO₂. Other polymeric preceramic films include those described in U.S. Pat. No. 6,803,660 to Gates et al. (October 2004).

Substrates can have any suitable dimensions, such as 200 mm or 300 mm diameter wafers, as well as, rectangular, square panes, or even rolled sheets. Substrates can be doped or non-doped, patterned or non-patterned. In many applications films can advantageously be flexible, and can inherently exhibit piezoelectric properties or can be stretched or otherwise processed to piezoelectric properties.

The photoresist is preferably applied by spin coating. In such operations a viscous, liquid solution of photoresist is dispensed onto the substrate, and the substrate is spun rapidly to produce a uniformly thick layer. The spin coating typically runs at 200 to 800 RPM for 30 to 60 seconds, and produces a layer between 2.5 and 0.5 μM thick. The photoresist-coated substrate is then preferably “soft-baked” or “prebaked” to drive off excess solvent, typically at 60 to 100° C. for 5 to 30 minutes. After prebaking, the photoresist is exposed to a pattern of intense ultraviolet or other light waves, and then portions are removed by a developer. Metal-ion-free developers are preferred, including tetramethylammonium hydroxide (TMAH) A post-exposure bake can advantageously be performed before developing, typically to help reduce standing wave phenomena caused by the destructive and constructive interference patterns of the incident light. The resulting intermediary is then “hard-baked”, typically at 120 to 180° C. for 20 to 30 minutes.

The photoresist can be patterned in a manner that provides very fine spaces for conductor lines. Preferred conductor line widths are ≦25 μM, ≦15 μM, ≦5 μM and even ≦1 μM, and the Drawing herein should be interpreted to support such fine line widths.

In FIG. 1C the non-protected areas of the substrate are subjected to a reducing atmosphere, and heated sufficiently to reduce such areas to form conductive metal traces 112. All suitable reducing gas or gasses are contemplated, most especially hydrogen, hydrazine vapor, cracked ammonia, deuterium and forming gas (a mixture of H₂ with He, N₂, or Ar). The process has similarities to that found in U.S. Pat. No. 6,158,246 to Borrelli et al. (December 2000), which teach depositing a protecting layer onto glass, and then subjecting the glass to a reducing atmosphere to color the unprotected areas. It is appreciated that reducing gasses have been used to remove photoresists, see e.g., US 2007/0045227 to Wu et al. (March 2007), so that chemical compositions of the mask and reducing gasses, as well as process parameters, should be properly chosen to accomplish the needed reduction of the metal oxide in the surface of the substrate 110, while maintaining at least some of the mask 120.

Alternately, a plasma comprised of Ar/H₂/H₃N can be used to reduce the non-protected areas of the substrate. The advantage is that the temperature due to self heating, etc., is sufficiently low (<100° C.) that substrates may be protected using standard commercially available photoresists thereby simplifying the masking process.

Once the conductive traces 112 are formed, they can be thickened in any suitable manner, including for example electroplating. In FIG. 1D, the additional thickness is identified as component 113. Suitable methods can be found in the prior art, including the electroless deposition processes found in U.S. Pat. No. 4,144,118 to Stahl (March 1979).

If no additional thickness is added to the trace, the mask 120 can be removed abrasively, by chemical and/or mechanical polishing. If additional thickness was added, however, the mask will likely be removed using either a liquid (“wet”) “resist stripper”, which chemically alters the resist so that it no longer adheres to the substrate. Alternatively, the photoresist mask 120 may be removed by a nonoxidizing acid such as methane sulfonic acid, or by a plasma containing oxygen, in a process called ashing. FIG. 1E shows the intermediate device with the mask removed.

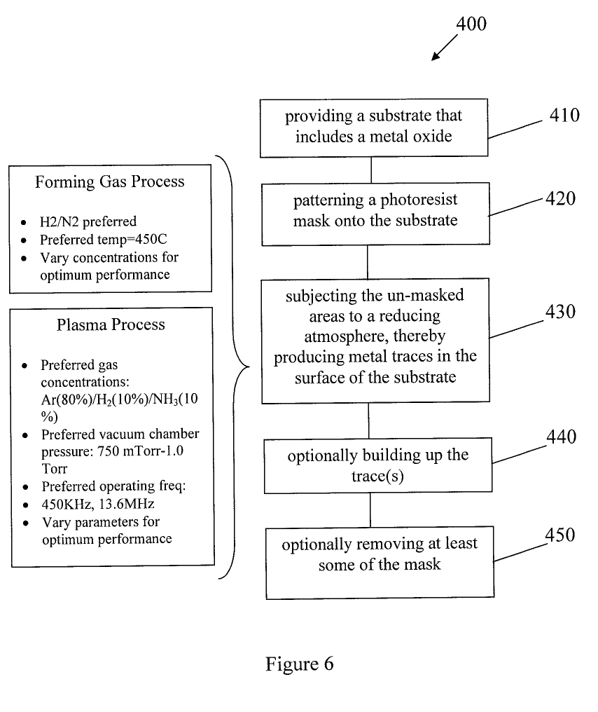

In FIG. 6 preferred methods of manufacturing a circuit 400 comprise the steps of: providing a substrate that includes a metal oxide 410; patterning a photoresist mask onto the substrate 420; subjecting the un-masked areas to a reducing atmosphere, thereby producing metal traces in the surface of the substrate 430; optionally building up the trace(s) 440; and optionally removing at least some of the mask 450.

It should be apparent to those skilled in the art that many more modifications besides those already described are possible without departing from the inventive concepts herein. Moreover, in interpreting the disclosure, all terms should be interpreted in the broadest possible manner consistent with the context. In particular, the terms “comprises” and “comprising” should be interpreted as referring to elements, components, or steps in a non-exclusive manner, indicating that the referenced elements, components, or steps could be present, or utilized, or combined with other elements, components, or steps that are not expressly referenced. Where the specification claims refers to at least one of something selected from the group consisting of A, B, C . . . and N, the text should be interpreted as requiring only one element from the group, not A plus N, or B plus N, etc.

What is claimed is:

1. A circuit comprising a high temperature flexible metal oxide-containing substrate upon which is disposed a conductor line having a width of ≦50 μM.

2. The circuit of claim 1, wherein the flexible substrate has a glass temperature of at least 300° C.

3. The circuit of claim 1, wherein the flexible substrate has a glass temperature of at least 400° C.

4. The circuit of claim 1, wherein the pre-ceramic includes PZT.

4. The circuit of claim 1, wherein the pre-ceramic includes BeO.

5. An intermediate comprising the circuit of claim 1, and a reducing gas in contact with the circuit.

6. The circuit of claim 1, further comprising a protective coating over a portion of the pre-ceramic.

7. An intermediate comprising the circuit of claim 1, and a plasma reducing gas in contact with the circuit.

8. The circuit of claim 1, wherein the pre-ceramic is disposed according to a deposit pattern.

9. The circuit of claim 1, wherein the conductor line has a width ≦25 μM.

10. The circuit of claim 1, wherein the conductor line has a width ≦15 μM.

11. The circuit of claim 1, wherein the conductor line has a width ≦5 μM.

12. The circuit of claim 1, wherein the conductor line has a width ≦1 μM.

13. The circuit of claim 1, wherein the conductor is coupled to a mechanical actuator.

14. The circuit of claim 12, wherein the actuator is fluidly coupled to a nozzle.

15. The circuit of claim 13, wherein the nozzle is fluidly coupled to a fluid reservoir.

16. The circuit of claim 1, wherein the circuit has at least 5 layers.

17. The circuit of claim 1, wherein the actuator comprises a piezoelectric material.
